(19) United States
(12) Patent Application Publication
(10) Pub. No.: US 2025/0218741 A1
(43) Pub. Date: Jul. 3, 2025

(54) SUBSTRATE TREATING APPARATUS AND METHOD

(71) Applicant: SEMES CO., LTD., Cheonan-si (KR)

(72) Inventor: Jin Hyeok KIM, Gyeongsangbuk-do (KR)

(73) Assignee: SEMES CO., LTD., Cheonan-si (KR)

(21) Appl. No.: 18/938,775

(22) Filed: Nov. 6, 2024

(30) Foreign Application Priority Data
Dec. 28, 2023 (KR) 10-2023-0195002

(51) Int. Cl. H01J 37/32; H01L 21/67; H01L 21/683

(52) U.S. Cl. CPC H01J 37/32642; H01J 37/32449; H01J 37/32724; H01J 37/32862; H01J 2237/334; H01L 21/67034; H01L 21/6833

(57) ABSTRACT

A substrate treating apparatus and method is provided, in which deposition of a by-product on an area between a focus ring and a dielectric layer included in an electrostatic chuck may be suppressed during a treating process of the substrate or a cleaning process of a process chamber. The substrate treating apparatus comprises an electrostatic chuck supporting a substrate; a focus ring surrounding an outer edge area of a dielectric layer included in the electrostatic chuck; and a by-product removal unit preventing a by-product generated in a process of treating the substrate from being adsorbed or remaining in an area between the dielectric layer and the focus ring.

### CROSS-REFERENCE TO RELATED APPLICATION

This application claims priority from Korean Patent Application No. 10-2023-0195002 filed on Dec. 28, 2023, in the Korean Intellectual Property Office and all the benefits accruing therefrom under 35 U.S.C. 119, the contents of which in its entirety are herein incorporated by reference.

### BACKGROUND

### Technical Field

The present disclosure relates to a substrate treating apparatus and method.

### Description of the Related Art

When a substrate is treated using plasma, a fluorine-based gas, a carbon-based gas, or the like may be used as a process gas. The process gas may be combined with a film material of the substrate or a coating layer of a part in a process chamber during a plasma process, thereby generating by-products.

After the plasma process is completed, an in-situ dry cleaning (ISD) process may be performed to remove gas and by-products remaining in the process chamber. However, it is difficult to completely remove the by-products even through the ISD process. The by-products that have not been completely removed may act as particle sources or defect sources, thereby shortening a preventive maintenance cycle and deteriorating the yield of semiconductor products.

Meanwhile, as the by-products are deposited on an area between an electrostatic chuck (ESC) supporting the substrate and a focus ring surrounding an outer edge area of the electrostatic chuck during the ISD process, arcing may be generated around the substrate, resulting in poor cleaning efficiency of the process chamber.

### BRIEF SUMMARY

An object of the present disclosure is to provide a substrate treating apparatus and method in which deposition of by-products on an area between a focus ring and a dielectric layer included in an electrostatic chuck may be suppressed during a treating process of the substrate or a cleaning process of a process chamber.

The objects of the present disclosure are not limited to those mentioned above and additional objects of the present disclosure, which are not mentioned herein, will be clearly understood by those skilled in the art from the following description of the present disclosure.

A substrate treating apparatus according to one aspect of the present disclosure devised to achieve the above objects comprises an electrostatic chuck supporting a substrate; a focus ring surrounding an outer edge area of a dielectric layer included in the electrostatic chuck; and a by-product removal unit preventing a by-product generated in a process of treating the substrate from being adsorbed to or remaining in an area between the dielectric layer and the focus ring.

A substrate treating apparatus according to another aspect of the present disclosure devised to achieve the above objects comprises a chamber housing providing a space in which a substrate is treated; a substrate support unit disposed inside the chamber housing, supporting the substrate by including a base plate, a dielectric layer adsorbing and supporting the substrate seated on an upper portion in a state that it is disposed on the base plate, and a focus ring surrounding an outer edge area of the dielectric layer; a showerhead unit disposed inside the chamber housing, providing a process gas; a plasma generating unit generating plasma for treating the substrate inside the chamber housing by using the process gas; and a by-product removal unit preventing a by-product generated in a process of treating the substrate to have a shape of a polymer or particle, from being adsorbed to or remaining in an area between the dielectric layer and the focus ring, wherein the by-product removal unit includes an inert gas supply module for spraying an inert gas into the area between the dielectric layer and the focus ring, and a drain module for removing the by-product from the area between the dielectric layer and the focus ring, the inert gas supply module sprays the inert gas upward in the area between the dielectric layer and the focus ring, provides the inert gas while the substrate is treated or the electrostatic chuck and the focus ring are cleaned after the treatment of the substrate is completed, sprays the inert gas at high pressure which is higher than a pressure for supplying a refrigerant to a cooling member installed in the electrostatic chuck or a pressure for supplying a cleaning gas to the electrostatic chuck, controls the pressure for spraying the inert gas independently of control of the pressure for supplying the refrigerant to the cooling member installed in the electrostatic chuck or control of the pressure for supplying the cleaning gas to the electrostatic chuck, and includes an inert gas supply source storing and providing the inert gas, and an inert gas moving line formed by passing through the base plate and the dielectric layer and connected to the inert gas supply source to provide a moving path of the inert gas, the inert gas moving line is provided as a plural number, and each of the plurality of inert gas moving lines independently provides the moving path of the inert gas, and the plurality of inert gas moving lines are disposed to be spaced apart from each other at a predetermined interval in the area between the dielectric layer and the focus ring, the drain module removes the by-product downward from the area between the dielectric layer and the focus ring, and removes the by-product while the substrate is treated or the electrostatic chuck and the focus ring are cleaned after the treatment of the substrate is completed, and includes a by-product moving line formed by passing through the base plate and the dielectric layer, providing a moving path of the by-product, and a drain pump connected to the by-product moving line, and the by-product moving line is provided as a plural number, and each of the plurality of by-product moving lines independently provides the moving path of the by-product, and the plurality of by-product moving lines are disposed to be spaced apart from each other at a predetermined interval in the area between the dielectric layer and the focus ring, and the plurality of inert gas moving lines are respectively disposed in the area where the plurality of inert gas moving lines are spaced apparat from each other.

A substrate treating method according to one aspect of the present disclosure devised to achieve the above objects comprises treating a substrate by using a substrate treating apparatus; cleaning the inside of the substrate treating apparatus when the substrate is completely treated; and removing a by-product generated in the process of treating the substrate while spraying an inert gas into an area between a focus ring and a dielectric layer included in a substrate support unit of the substrate treating apparatus, wherein the spraying of the inert gas and the removal of the by-product are performed while the substrate is treated or the inside of the substrate treating apparatus is cleaned.

Details of the other embodiments are included in the detailed description and drawings.

In the substrate treating apparatus and method according to some embodiments of the present disclosure, deposition of the by-product on the area between the focus ring and the dielectric layer included in the electrostatic chuck may be suppressed through the by-product removal unit, which includes the inert gas supply module and the drain module, during the treating process of the substrate and the cleaning process of the process chamber.

The effects according to the embodiment of the present disclosure are not limited to those mentioned above, and more various effects are included in the following description of the present disclosure.

### BRIEF DESCRIPTION OF THE DRAWINGS

The above and other aspects and features of the present disclosure will become more apparent by describing in detail exemplary embodiments thereof with reference to the attached drawings, in which:

FIGS. 1 to 3 are schematic cross-sectional views illustrating an internal structure of a substrate treating apparatus according to some embodiments of the present disclosure;

FIG. 4 is a schematic cross-sectional view illustrating a substrate support unit (electrostatic chuck) of a substrate treating apparatus according to some embodiments of the present disclosure;

FIGS. 5 and 6 are schematic cross-sectional views illustrating a portion where a focus ring is disposed in a substrate treating apparatus according to some embodiments of the present disclosure;

FIGS. 7 and 8 are schematic cross-sectional views illustrating a portion where a by-product removal unit of a substrate treating apparatus according to some embodiments of the present disclosure; and

FIG. 9 is a flow chart illustrating a substrate treating method according to some embodiments of the present disclosure.

### DETAILED DESCRIPTION OF THE DISCLOSURE

Hereinafter, the preferred embodiment of the present disclosure will be described in detail with reference to the accompanying drawings. Advantages and features of the present disclosure and methods of achieving the advantages and features will be apparent from the following embodiments that will be described in more detail with reference to the accompanying drawings. It should be noted, however, that the present disclosure is not limited to the following embodiments, and may be implemented in various forms. The embodiments are provided only to disclose the present disclosure and let those skilled in the art understand the scope of the present disclosure. In the drawings, the embodiments of the present disclosure are defined by the scope of claims. The same reference numerals denote the same elements throughout the specification.

The terms used herein are for the purpose of embodiments, and are not intended to be limit the present disclosure. In the present disclosure, unless referred to the contrary, the singular forms are intended to include the plural forms. The terms “comprises” and/or “comprising” used herein specify the presence of stated elements, steps, operations and/or targets but do not preclude the presence or addition of one or more other elements, steps, operations and/or targets.

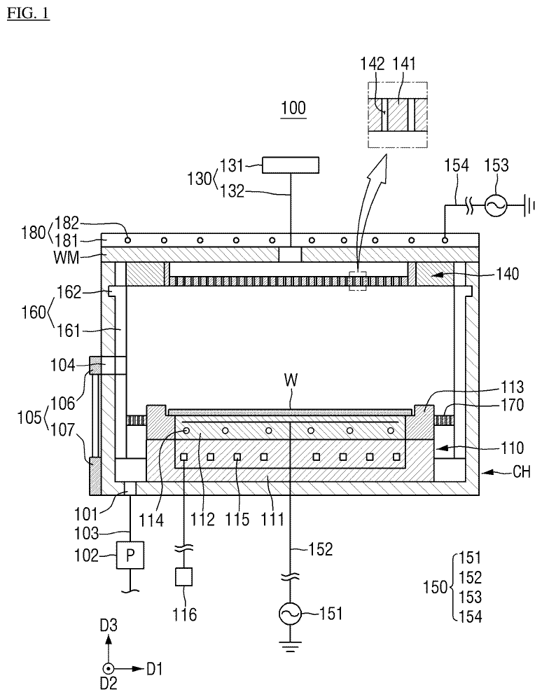

FIG. 1 is a schematic cross-sectional view illustrating an internal structure of a substrate treating apparatus according to some embodiments of the present disclosure.

Referring to FIG. 1, the substrate treating apparatus 100 according to some embodiments of the present disclosure may include a chamber housing CH, a substrate support unit 110, a process gas supply unit 130, a showerhead unit 140, a plasma generating unit 150, a liner unit 160, a baffle unit 170, a window module WM, and an antenna unit 180.

In this case, a first direction D1 and a second direction D2 may constitute a plane in a horizontal direction. The first direction D1 may be a front-rear direction, and the second direction D2 may be a left-right direction. Alternatively, the first direction D1 may be a left-right direction, and the second direction D2 may be a front-rear direction. A third direction D3 is a height direction, and is a direction perpendicular to the plane constituted by the first direction D1 and the second direction D2. The third direction D3 may be a vertical direction.

The substrate treating apparatus 100 according to some embodiments of the present disclosure may treat a substrate W by using plasma. The substrate treating apparatus 100 may treat the substrate W in a dry method.

For example, the substrate treating apparatus 100 may treat the substrate W in a vacuum environment. The substrate treating apparatus 100 may treat the substrate W by using an etching process, but is not limited thereto. The substrate treating apparatus 100 may also treat the substrate W by using a deposition process or a cleaning process.

The chamber housing CH provides a space in which a process of treating the substrate W by using plasma, that is, a plasma process is performed. A surface of the chamber housing CH may be made of alumite on which an anodized film is formed, and the inside thereof may be configured to be airtight. The chamber housing CH may be provided in a cylindrical shape, but is not limited thereto, and may be provided in other shapes. The chamber housing CH may have an exhaust hole 101 therebelow.

The exhaust hole 101 may be connected to an exhaust line 103 on which a pump 102 is mounted. The exhaust hole 101 may discharge reaction by-products generated during the plasma process and gas remaining inside the chamber housing CH to the outside of the chamber housing CH through the exhaust line 103. In this case, an inner space of the chamber housing CH may be decompressed.

An opening 104 may be formed to pass through a sidewall of the chamber housing CH. The opening 104 may be provided as a passage through which the substrate W enters and exits the chamber housing CH.

For example, the opening 104 may be configured to be automatically opened and closed by a door assembly 105.

The door assembly 105 may include an outer door 106 and a door driver 107.

The outer door 106 may open and close the opening 104 on an outer wall of the chamber housing CH. The outer door 106 may be moved in the height direction D3 of the substrate treating apparatus 100 under the control of the door driver 107.

The door driver 107 may operate using at least one element selected from a motor, a hydraulic cylinder or a pneumatic cylinder.

The substrate support unit 110 is installed in a lower area inside the chamber housing CH. The substrate support unit 110 may adsorb and support the substrate W by using an electrostatic force.

For example, the substrate support unit 110 may be provided as an electrostatic chuck (ESC), but is not limited thereto, and the substrate support unit 110 may support the substrate W by using various other methods such as vacuum and mechanical clamping.

When provided as an electrostatic chuck (ESC), the substrate support unit 110 may include a base plate 111 and a dielectric layer 112.

The dielectric layer 112 is disposed on the base plate 111, and may adsorb and support the substrate W mounted thereon. For example, the dielectric layer 112 may be formed of, for example, ceramic.

The base plate 111 may be formed of a material having excellent corrosion resistance and heat resistance. For example, the base plate 111 may be provided as an aluminum body.

Although not shown in FIG. 1, the substrate support unit 110 may further include a bonding layer.

The bonding layer may bond the base plate 111 to the dielectric layer 112. For example, the bonding layer may be formed to include a polymer.

The ring structure 113 is provided to surround an outer edge area of the dielectric layer 112. The ring structure 113 may serve to concentrate ions on the substrate W when the plasma process is performed inside the chamber housing CH. The ring structure 113 may be formed of a silicon material. For example, the ring structure 113 may be provided as a focus ring.

Although not shown in FIG. 1, the ring structure 113 may further include an edge ring. The edge ring may be provided below or outside the focus ring.

The edge ring may serve to prevent a side of the dielectric layer 112 from being damaged by plasma. The edge ring may be formed of an insulator material, for example, ceramic or quartz.

A heating member 114 and a cooling member 115 are provided to maintain the substrate W at a process temperature when a substrate treating process is performed inside the chamber housing CH.

The heating member 114 may be installed inside the dielectric layer 112, and may be provided as a heating wire.

The cooling member 115 may be installed inside the base plate 111, and may be provided as a cooling pipe through which a refrigerant moves.

A cooling device (chiller) 116 may supply the refrigerant to the cooling member 115. The cooling device 116 may use cooling water as the refrigerant, but is not limited thereto, and may use helium (He) gas. Alternatively, the cooling device 116 may use both cooling water and helium gas as the refrigerant.

Meanwhile, the heating member 114 may not be provided in the substrate support unit 110.

The process gas supply unit 130 provides a process gas to the inner space of the chamber housing CH. The process gas supply unit 130 may provide the process gas to the inner space of the chamber housing CH through a hole formed by passing through an upper cover of the chamber housing CH, that is, the window module WM, but is not limited thereto. The process gas supply unit 130 may also provide the process gas to the inner space of the chamber housing CH through a hole formed by passing through the sidewall of the chamber housing CH.

The process gas supply unit 130 may include a process gas supply source 131 and a process gas supply pipe 132.

The process gas supply source 131 may provide a gas used for treating the substrate W as a process gas. The process gas supply source 131 may be provided as a single number in the substrate treating apparatus 100, but may be provided as a plural number without being limited thereto. When a plurality of process gas supply sources 131 are provided in the substrate treating apparatus 100, the plurality of process gas supply sources 131 may provide the same type of process gas, but are not limited thereto, and may provide different types of process gases.

The showerhead unit 140 sprays the process gas provided from the process gas supply source 131 onto the entire area of the substrate W disposed in the inner space of the chamber housing CH. The showerhead unit 140 may be connected to the process gas supply source 131 through the process gas supply pipe 132.

The showerhead unit 140 is disposed in the inner space of the chamber housing CH, and may include a plurality of gas feeding holes 142.

The plurality of gas feeding holes 142 may be formed to pass through a surface of a body 141 in the vertical direction D3. The plurality of gas feeding holes 142 may be formed on the body 141 so that they are spaced apart from each other at a predetermined interval.

The showerhead unit 140 may uniformly spray the process gas to the entire area of the substrate W through the plurality of gas feeding holes 142.

The showerhead unit 140 may be installed inside the chamber housing CH to face the substrate support unit 110 in the vertical direction D3. The showerhead unit 140 may be provided to have a larger diameter than the dielectric layer 112, but is not limited thereto. The showerhead unit 140 may be provided to have the same diameter as that of the dielectric layer 112. The showerhead unit 140 may be formed of a silicon material, but is not limited thereto. The showerhead unit 140 may be also formed of a metal material.

Although not shown in FIG. 1, the showerhead unit 140 may be divided into a plurality of units.

For example, the showerhead unit 140 may be divided into three modules such as a first head module, a second head module, and a third head module.

The first head module may be disposed at a position corresponding to a center zone of the substrate W.

The second head module may be disposed to surround an outer edge of the first head module. The second head module may be disposed at a position corresponding to a middle zone of the substrate W.

The third head module may be disposed to surround an outer edge of the second head module. The third head module may be disposed at a position corresponding to an edge zone of the substrate W.

The plasma generating unit 150 generates plasma from a gas remaining in a discharge space.

In this case, the discharge space is the inner space of the chamber housing CH, and may be a space formed between the showerhead unit 140 and the window module WM. Alternatively, the discharge space may be a space formed between the substrate support unit 110 and the showerhead unit 140.

When the discharge space is the space formed between the substrate support unit 110 and the showerhead unit 140, the discharge space may be divided into a plasma area and a process area.

The plasma area may be formed to be higher than the process area.

The plasma generating unit 150 may generate plasma in the discharge space by using an inductively coupled plasma (ICP) source, that is, an inductively coupled plasma source.

For example, the plasma generating unit 150 may generate plasma in the discharge space by using the substrate support unit 110 and the antenna unit 180 as a first electrode (lower electrode) and a second electrode (upper electrode), respectively, but the present embodiment is not limited thereto.

The plasma generating unit 150 may generate plasma in the discharge space by using a capacitively coupled plasma (CCP) source, that is, a capacitively coupled plasma source.

For example, the plasma generating unit 150 may generate plasma in the discharge space by using the substrate support unit 110 and the showerhead unit 140 as a first electrode (lower electrode) and a second electrode (upper electrode), respectively.

In this case, a case that the plasma generating unit 150 is provided as an ICP source will be described, and a case that the plasma generating unit 150 is provided as a CCP source will be described later.

The plasma generating unit 150 may include a first high frequency power source 151, a first transmission line 152, a second high frequency power source 153, and a second transmission line 154.

The first high frequency power source 151 applies RF power to the first electrode. The first high frequency power source 151 may serve as a plasma source for generating plasma in the chamber housing CH, but is not limited thereto. The first high frequency power source 151 may also serve to control characteristics of plasma in the chamber housing CH together with the second high frequency power source 153.

The first high frequency power source 151 may be provided as a plural number in the substrate treating apparatus 100. In this case, the plasma generating unit 150 may include a first matching network electrically connected to each of the first high frequency power sources.

The first matching network may serve to match the frequency powers and apply them to the first electrode when frequency powers of different magnitudes are input from the plurality of first high frequency power sources.

The first transmission line 152 may connect the first electrode to GND.

The first high frequency power source 151 may be installed on the first transmission line 152, but is not limited thereto. The first transmission line 152 may connect the first electrode to the first high frequency power source 151. For example, the first transmission line 152 may be provided as an RF rod.

The second high frequency power source 153 applies RF power to the second electrode. The second high frequency power source 153 may serve to control characteristics of plasma in the chamber housing CH. For example, the second high frequency power source 153 may serve to control ion bombardment energy in the chamber housing CH.

The second high frequency power source 153 may be provided as a plural number in the substrate treating apparatus 100. In this case, the plasma generating unit 150 may include a second matching network electrically connected to each of the second high frequency power sources.

The second matching network may serve to match the frequency powers and apply them to the second electrode when frequency powers of different magnitudes are input from the plurality of second high frequency power sources.

The second transmission line 154 connects the second electrode with a GND.

The second high frequency power source 153 may be installed on the second transmission line 154.

The liner unit 160 may be defined as a wall liner, and protects the inside of the chamber housing CH from arc discharge occurring during a process of exciting a process gas or impurities generated during the substrate treating process. The liner unit 160 may be formed to cover an inner wall of the chamber housing CH.

The liner unit 160 may include a support ring 162 on an upper portion of the body 161.

The support ring 162 may be protruded from the upper portion of the body 161 in an outward direction D1, and may serve to fix the body 161 to the chamber housing CH.

The baffle unit 170 serves to exhaust process by-products or an unreacted gas of plasma inside the chamber housing CH to the outside. The baffle unit 170 may be installed in a space between the substrate support unit 110 and the inner wall (or the liner unit 160) of the chamber housing CH, and may be installed to be adjacent to the exhaust hole 101. The baffle unit 170 may be provided in an annular ring shape between the substrate support unit 110 and the inner wall of the chamber housing CH.

The baffle unit 170 may include a plurality of slot holes passing through the body in the vertical direction D3 to control a flow of the process gas in the chamber housing CH. The baffle unit 170 may be formed of a material having etching resistance to minimize damage or deformation by radicals or the like in the inner space of the chamber housing CH in which plasma is generated. For example, the baffle unit 170 may be formed to include quartz.

The window module WM serves as an upper cover of the chamber housing CH which seals the inner space of the chamber housing CH. The window module WM may be provided separately from the chamber housing CH, but is not limited thereto, and may be also provided integrally with the chamber housing CH. The window module WM may be formed of an insulating material as a dielectric window.

For example, the window module WM may be formed of alumina. When the plasma process is performed in the inner space of the chamber housing CH, the window module WM may include a coating film on its surface to suppress generation of particles.

The antenna unit 180 serves to excite the process gas into plasma by generating a magnetic field and an electric field inside the chamber housing CH. The antenna unit 180 may operate using RF power supplied from the second high frequency power source 153. The antenna unit 180 may be provided on an upper portion of the chamber housing CH.

For example, the antenna unit 180 may be provided on the window module WM, but is not limited thereto, and the antenna unit 180 may be provided on the sidewall of the chamber housing CH.

The antenna unit 180 may include an antenna 182 inside or on a surface of the body 181.

The antenna 182 may be provided to form a closed loop by using a coil. The antenna 182 may be formed in a spiral shape along a width direction D1 of the chamber housing CH or other various shapes.

The antenna unit 180 may be formed to have a planar type structure, but is not limited thereto, and the antenna unit 180 may be formed to have a cylindrical type. When the antenna unit 180 is formed to have a planar type structure, it may be provided on the upper portion of the chamber housing CH. When the antenna unit 180 is formed to have a cylindrical structure, it may be provided to surround the outer wall of the chamber housing CH.

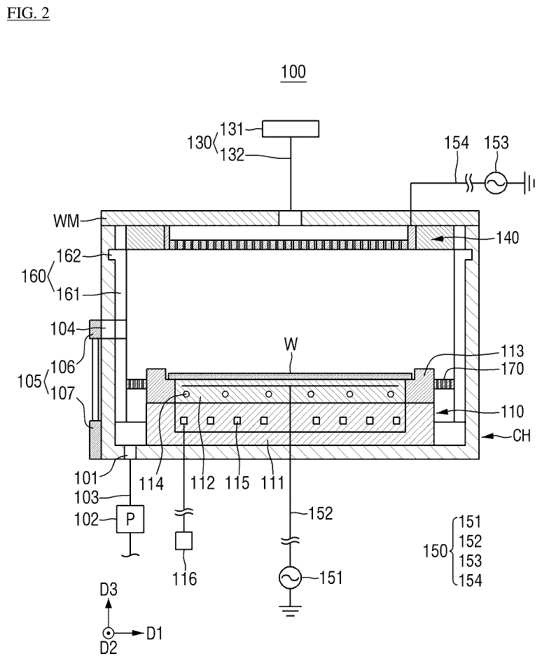

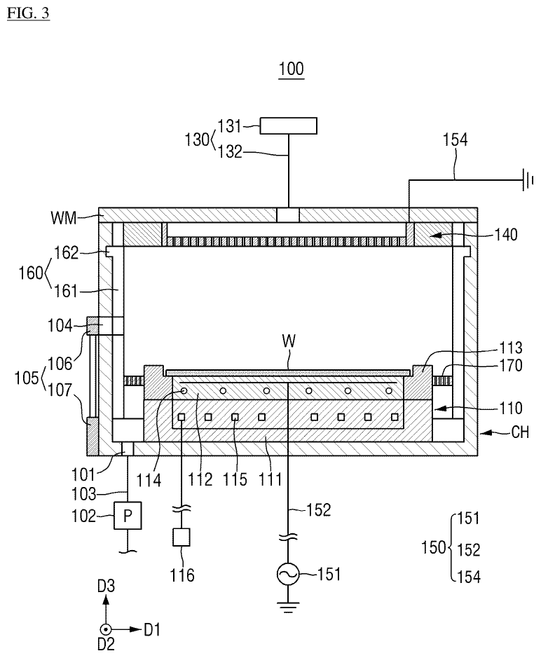

As described above, the case that the plasma generating unit 150 is provided as an ICP source has been described with reference to FIG. 1. Hereinafter, the case that the plasma generating unit 150 is provided as a CCP source will be described with reference to FIGS. 2 and 3. Hereinafter, a redundant description compared with the case of FIG. 1 will be omitted, portions corresponding to differences from the case of FIG. 1 will be described.

FIGS. 2 and 3 are schematic cross-sectional views illustrating an internal structure of a substrate treating apparatus according to some embodiments of the present disclosure.

Referring to FIGS. 2 and 3, the substrate treating apparatus 100 according to some embodiments of the present disclosure may include a chamber housing CH, a substrate support unit 110, a process gas supply unit 130, a showerhead unit 140, a plasma generating unit 150, a liner unit 160, a baffle unit 170, and a window module WM.

That is, the substrate treating apparatus 100 of FIGS. 2 and 3 may not include the antenna unit 180 as compared with the substrate treating apparatus 100 of FIG. 1.

As shown in FIG. 2, the plasma generating unit 150 may include a first high frequency power source 151, a first transmission line 152, a second high frequency power source 153 and a second transmission line 154, but is not limited thereto. The plasma generating unit 150 may include a first high frequency power source 151, a first transmission line 152 and a second transmission line 154, as shown in FIG. 3.

That is, the plasma generating unit 150 of FIG. 3 may not include the second high frequency power source 153 as compared with the plasma generating unit 150 of FIG. 2.

In case of the example according to FIG. 1, the second transmission line 154 may be connected to the antenna 182 of the antenna unit 180.

The second high frequency power source 153 may apply RF power to the antenna 182 of the antenna unit 180.

In case of the example according to FIG. 2, the second transmission line 154 may be connected to the body 141 of the showerhead unit 140.

The second high frequency power source 153 may apply RF power to the body 141 of the showerhead unit 140.

In case of the example according to FIG. 2, the second high frequency power source 153 may be installed on the second transmission line 154.

In case of the example according to FIG. 3, the second high frequency power source 153 may not be installed on the second transmission line 154.

When the second high frequency power source 153 is installed on the second transmission line 154, the plasma generating unit 150 may apply a multi-frequency to the substrate treating apparatus 100.

Although not shown in FIGS. 1 to 3, the substrate treating apparatus 100 according to some embodiments of the present disclosure may further include a control device.

The control device serves to control the entire operation of each unit constituting the substrate treating apparatus 100. The control device may control the entire substrate treating process of the substrate treating apparatus 100.

The control device may include a processor that controls each component of the substrate treating apparatus 100, a network that performs wired or wireless communication with each component, one or more instructions related to a function or operation for controlling each component, and a storage means for storing processing recipes including instructions, various data and the like. The control device may further include a user interface that includes an input means for performing a command input manipulation or the like by an operator to manage the substrate treating apparatus 100, and an output means for visualizing and displaying an actuation status of the substrate treating apparatus 100. The control device may be provided as a computing device for data processing and analysis and command transmission.

The instruction may be provided in the form of a computer program or an application. The computer program may include one or more instructions and be stored in a computer-readable recording medium. The instruction may include a code generated by a compiler, a code executed by an interpreter, and the like.

The storage means may be provided as one or more storage media selected from a flash memory, an HDD, an SSD, a card-type memory, a RAM, an SRAM, a ROM, an EEPROM, a PROM, a magnetic memory, a magnetic disk and an optical disk.

Meanwhile, the process gas supply unit 130 may provide the process gas into the chamber housing CH so that plasma for treating the substrate W may be generated.

For example, the process gas supply unit 130 may provide a fluorine-based gas, a carbon-based gas and the like as the process gas.

The fluorine-based process gas and the carbon-based process gas may be combined with a film material of the substrate W during the substrate treating process to generate by-products. The fluorine-based process gas and the carbon-based process gas may be combined with a coating layer formed in a part inside the chamber housing CH during the substrate treating process to generate by-products.

The by-products may be adsorbed to the part. For example, the part may be a chamber housing CH, a ring structure (focus ring) 113, a baffle unit 170, etc. For example, the by-products may have a shape of a polymer or particle.

The by-products may be removed through an in-situ dry cleaning (ISD) process after the substrate treating process. However, a portion of the carbon-based polymer or the Si-based polymer may be only removed, and in case of YF-based polymer generated by combination with Y₂O₃ coating layer, it is very difficult to remove the polymer through the ISD process.

The by-products that cannot be removed even through the ISD process may continue to remain in the part.

The by-products remaining in the part may act as particle sources or defect sources as the number of processes is increased. The by-products remaining in the part may shorten a preventive maintenance cycle of the substrate treating apparatus 100, and may deteriorate the yield of semiconductor products produced through the substrate treating apparatus 100.

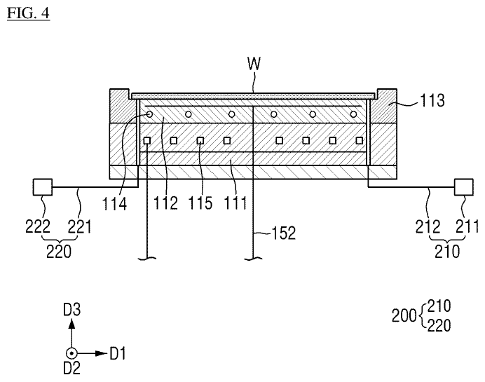

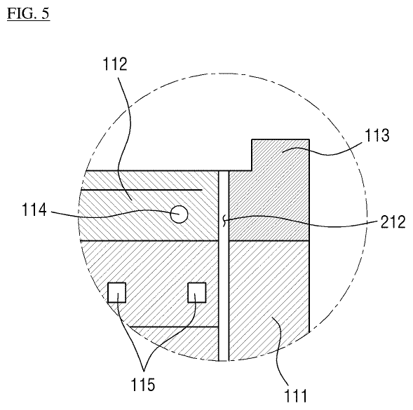

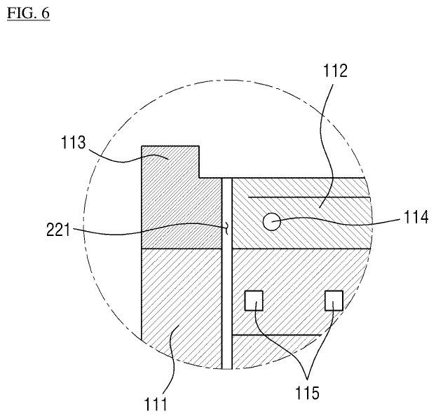

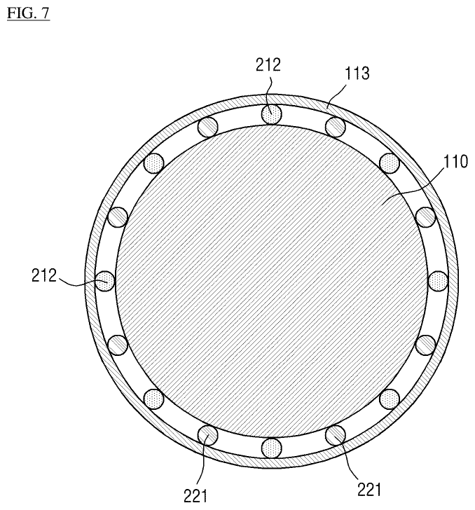

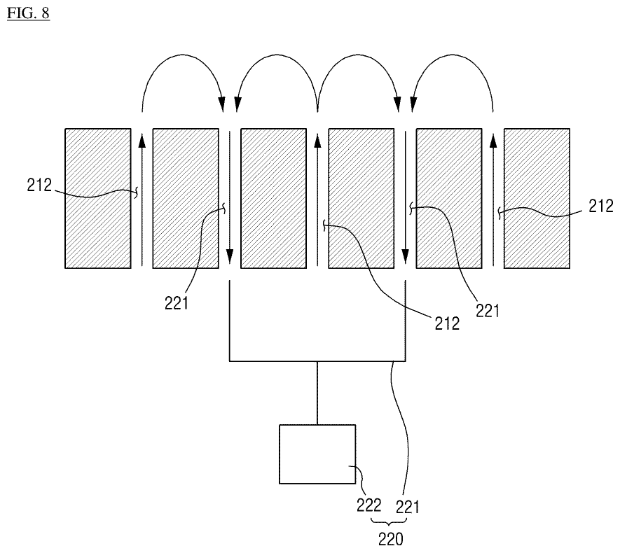

FIG. 4 is a schematic cross-sectional view illustrating a substrate support unit (electrostatic chuck) of a substrate treating apparatus according to some embodiments of the present disclosure. FIGS. 5 and 6 are schematic cross-sectional views illustrating a portion where a focus ring is disposed in a substrate treating apparatus according to some embodiments of the present disclosure. FIGS. 7 and 8 are schematic cross-sectional views illustrating a portion where a by-product removal unit of a substrate treating apparatus according to some embodiments of the present disclosure.

Referring to FIGS. 4 to 6, the substrate treating apparatus 100 according to some embodiments of the present disclosure may include a by-product removal unit 200. The by-product removal unit 200 serves to prevent by-products generated in the process of treating the substrate W from being adsorbed to or remained in an area between the dielectric layer 112 included in an electrostatic chuck (the substrate support unit 110) supporting the substrate and a focus ring (the ring structure 113) surrounding an outer edge area of the dielectric layer 112.

The by-product removal unit 200 may include an inert gas supply module 210 and a drain module 220.

The inert gas supply module 210 is configured to supply an inert gas, and allows the inert gas to be sprayed into the area between the dielectric layer 112 and the focus ring 113. In this case, the inert gas may include a gas such as helium (He), neon (Ne) and argon (Ar), a nitrogen gas, and the clean air.

The inert gas supply module 210 sprays the inert gas upward in the height direction D3 in the area between the dielectric layer 112 and the focus ring 113. The by-products may be prevented from being deposited on the area between the dielectric layer 112 and the focus ring 113 through the inert gas sprayed by the inert gas supply module 210.

The inert gas supply module 210 may provide the inert gas while the substrate W is treated. The by-products may be prevented from being deposited on the area between the dielectric layer 112 and the focus ring 113 in the process of treating the substrate W through the inert gas sprayed by the inert gas supply module 210.

The inert gas supply module 210 may provide the inert gas while cleaning the dielectric layer 112 and the focus ring 113 after the treatment of the substrate W is completed. That is, the by-products may be prevented from being deposited on the area between the dielectric layer 112 and the focus ring 113 in an in-situ dry cleaning (ISD) process of cleaning the inside of the process chamber, on which the treatment of the substrate W has been completed, through the inert gas injected by the inert gas supply module 210.

The inert gas supply module 210 may spray the inert gas at high pressure. The inert gas supply module 210 may spray the inert gas at a pressure higher than a pressure for supplying a refrigerant to the cooling member 115 installed in the electrostatic chuck 110.

The inert supply module 210 may control the pressure for spraying the inert gas independently of the control of the pressure for supplying the refrigerant to the cooling member 115 installed in the electrostatic chuck 110. This may be implemented under the control of the control device.

The inert gas supply module 210 may include an inert gas supply source 211 and an inert gas moving line 212.

The inert gas supply source 211 may include a storage tank for storing the inert gas. The inert gas supply source 211 may operate under the control of the control device. The inert gas supply source 211 may discharge the inert gas stored in the storage tank to the inert gas moving line 212.

The inert gas supply source 211 may be connected to the inert gas moving line 212.

A valve that may be opened and closed may be provided between the inert gas supply source 211 and the inert gas moving line 212. Alternatively, a valve that may be opened and closed may be provided on the inert gas moving line 212. When the valve is opened, the inert gas supply source 211 may discharge the inert gas to the inert gas moving line 212.

The inert gas moving line 212 may be provided to pass through the base plate 111 and the dielectric layer 112, which are included in the electrostatic chuck 110. One side of the inert gas moving line 212 may be connected to the inert gas supply source 211. The other side of the inert gas moving line 212 may be exposed to the inside of the chamber housing CH by passing through an upper surface of the dielectric layer 112. The inert gas moving line 212 provides a moving path of the inert gas supplied from the inert gas supply source 211.

The inert gas sprayed and discharged from one side to the other side of the inert gas moving line 212 may suppress adsorption of the by-products in the area between the focus ring 113 and the dielectric layer 112 of the electrostatic chuck 111.

Referring to FIGS. 7 and 8, the inert gas moving line 212 may be provided as a plural number, and each of the inert gas moving lines 212 may be provided to independently provide a moving path of the inert gas. In this case, both the inert gas supply source 211 and the inert gas moving line 212 may be provided as a plural number. Alternatively, only the inert gas moving line 212 may be provided as a plural number to be branched from one inert gas supply source 211.

When both the inert gas supply source 211 and the inert gas moving line 212 are provided as a plural number, the same number of the inert gas supply sources 211 and the inert gas moving lines 212 may be provided. The inert gas supply source 211 and the inert gas moving line 212, which constitute each set, may operate independently.

The plurality of inert gas moving lines 212 may be disposed to be spaced apart from each other at a predetermined interval in the area between the dielectric layer 112 and the focus ring 113. For example, when the area between the dielectric layer 112 and the focus ring 113 is formed in a circular shape, the plurality of inert gas moving lines 212 may be disposed to be spaced apart from each other along the circumference of the area between the dielectric layer 112 and the focus ring 113.

Referring to FIGS. 4 to 6, the drain module 220 is configured to remove the by-products, and allows the by-products to be sucked in and discharged from the area between the dielectric layer 112 and the focus ring 113, thereby removing the by-products.

The drain module 220 may remove the by-products from the area between the dielectric layer 112 and the focus ring 113 downward in the height direction D3, thereby suppressing the deposition of the by-products.

The drain module 220 may remove the by-products while the substrate W is treated. The by-products remaining in the area between the dielectric layer 112 and the focus ring 113 may be sucked and discharged to be removed by the drain module 220.

After the treatment of the substrate W is completed, the drain module 220 may remove the by-products while the dielectric layer 112 and the focus ring 113 are cleaned. That is, in the in-situ dry cleaning (ISD) process for cleaning the inside of the process chamber, on which the treatment of the substrate W has been completed, through the inert gas sprayed by the inert gas supply module 210, in order to prevent the by-products from being deposited on the area between the dielectric layer 112 and the focus ring 113, the by-products are removed. In this case, the drain module 220 may remove the by-products by allowing the by-products to be sucked and discharged while blocking the by-products from being floated or scattered into the chamber housing CH by the inert gas sprayed and discharged from the inert gas moving line 212.

The drain module 220 may remove the by-products at high pressure. The drain module 220 may allow the by-products to be sucked and discharged downward in the height direction D3 at high pressure. This may be implemented under the control of the control device.

The drain module 220 may include a by-product moving line 221 and a drain pump 222.

The by-product moving line 221 may be provided by passing through the base plate 111 and the dielectric layer 112, which are included in the electrostatic chuck 110. One side of the by-product moving line 221 may be connected to the drain pump 222. The other side of the by-product moving line 221 may be exposed to the inside of the chamber housing CH by passing through the upper surface of the dielectric layer 112. The by-product moving line 221 provides a discharge (moving) path of the by-products sucked from the area between the dielectric layer 112 and the focus ring 113.

The drain pump 222 may operate under the control of the control device. The drain pump 222 may suck and discharge the by-products at high pressure by the control device. For example, the drain pump 220 may have a shape of a turbo molecular pump (TMP).

The drain pump 222 may be connected to the by-product moving line 221.

A valve that may be opened and losed may be provided between the drain pump 222 and the by-product moving line 221. Alternatively, a valve that may be opened and closed may be provided on the by-product moving line 221. When the valve is opened, the drain pump 222 may allow the by-products to be sucked in and discharged from the area between the dielectric layer 112 and the focus ring 113 through the by-product moving line 221, thereby removing the by-products.

Referring to FIGS. 7 and 8, the by-product moving line 221 may be provided as a plural number, and each of the plurality of by-product moving lines 221 may be provided to independently provide a moving (discharge) path of the by-products. In this case, both the by-product moving line 221 and the drain pump 222 may be provided as a plural number. Alternatively, only the inert gas moving line 212 may be provided as a plural number to be branched from one drain pump 222.

When both the by-product moving line 221 and the drain pump 222 are provided as a plural number, the same number of the by-product moving lines 221 and the drain pump 222 may be provided. The by-product moving line 221 and the drain pump 222, which constitute each set, may operate independently.

The plurality of by-product moving lines 221 may be disposed to be spaced apart from each other at a predetermined interval in the area between the dielectric layer 112 and the focus ring 113. For example, when the area between the dielectric layer 112 and the focus ring 113 is formed in a circular shape, the plurality of by-product moving lines 221 may be disposed to be spaced apart from each other along the circumference of the area between the dielectric layer 112 and the focus ring 113.

Each of the plurality of by-product moving lines 221 may be disposed in the area in which the plurality of inert gas moving lines 212 are spaced apart from each other. That is, in the area between the dielectric layer 112 and the focus ring 113 of the substrate treating apparatus 100 according to some embodiments of the present disclosure, the plurality of inert gas moving lines 212 and the plurality of by-product moving lines 221 may be provided in an array of the inert gas moving line 212, the by-product moving line 221, the inert gas moving line 212 and the by-product moving line 221.

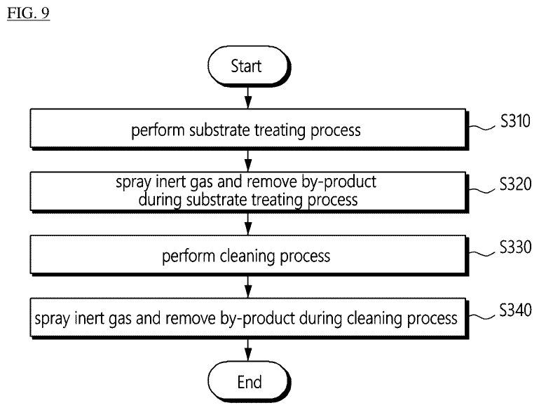

FIG. 9 is a flow chart illustrating a substrate treating method according to some embodiments of the present disclosure.

Referring to FIG. 9, when the substrate W is introduced into the substrate treating apparatus 100 according to some embodiments of the present disclosure, the substrate treating apparatus 100 performs a substrate treating process (S310). The substrate treating process may be a process of treating the substrate W by using plasma.

When the substrate treating process is performed, the inert gas supply module 210 of the by-product removal unit 200 sprays the inert gas upward in the height direction D3 toward the area between the dielectric layer 112 and the focus ring 113. Simultaneously, the drain module 220 of the by-product removal unit 200 sucks and discharges the by-products remaining in the area between the dielectric layer 112 and the focus ring 113 downward in the height direction D3, thereby removing the by-products (S320).

The inert gas may prevent the by-products from being generated. Alternatively, the inert gas may prevent the by-products from being adsorbed to the area between the dielectric layer 112 and the focus ring 113. The drain module 220 may suck and discharge the by-products in the area between the dielectric layer 112 and the focus ring 113, thereby preventing the by-products from being adsorbed or remaining.

When the substrate treating process is completed, the substrate treating apparatus 100 performs a cleaning process (S330). For example, the cleaning process may be an in-situ dry cleaning (ISD) process.

When the cleaning process is performed, the inert gas supply module 210 of the by-product removal unit 200 sprays the inert gas upward in the height direction D3 toward the area between the dielectric layer 112 and the focus ring 113. Simultaneously, the drain module 220 of the by-product removal unit 200 sucks and discharges the by-products remaining in the area between the dielectric layer 112 and the focus ring 113 downward in the height direction D3, thereby removing the by-products (S340).

The by-product removal unit 200 may spray the inert gas and at the same time suck and discharge the by-products during the treating process of the substrate and the cleaning process, but it is not limited thereto. The by-product removal unit 200 may spray the inert gas and at the same time suck and discharge the by-products while any one of the treating process of the substrate and the cleaning process is performed.

As described above, in the substrate treating apparatus and method according to some embodiments of the present disclosure, the deposition of the by-products on the area between the focus ring 113 and the dielectric layer 112 included in the electrostatic chuck 110 may be suppressed through the by-product removal unit 200, which includes the inert gas supply module 210 and the drain module 220, during the treating process of the substrate or the cleaning process of the process chamber.

Although the embodiments of the present disclosure have been described with reference to the accompanying drawings, it will be apparent to those skilled in the art that the present disclosure can be embodied in other specific forms without departing from the technical spirits and essential characteristics of the present disclosure. Thus, the above-described embodiments are to be considered in all respects as illustrative and not restrictive.

What is claimed is:

1. A substrate treating apparatus comprising:
an electrostatic chuck supporting a substrate;
a focus ring surrounding an outer edge area of a dielectric layer included in the electrostatic chuck; and
a by-product removal unit preventing a by-product generated in the process of treating the substrate from being adsorbed to or remaining in an area between the dielectric layer and the focus ring.

2. The substrate treating apparatus of claim 1, wherein the by-product removal unit includes:
an inert gas supply module allowing an inert gas to be sprayed into the area between the dielectric layer and the focus ring; and
a drain module removing the by-product by sucking or discharging the by-product remaining in the area between the dielectric layer and the focus ring or floated by the spray of the inert gas.

3. The substrate treating apparatus of claim 2, wherein the inert gas supply module sprays the inert gas from a lower side in a height direction of a base plate included in the electrostatic chuck to an upper side in a height direction of the dielectric layer by passing through the base plate and the dielectric layer in the area between the dielectric layer and the focus ring.

4. The substrate treating apparatus of claim 2, wherein the inert gas supply module provides the inert gas while the substrate is treated.

5. The substrate treating apparatus of claim 2, wherein the inert gas supply module provides the inert gas while the dielectric layer and the focus ring are cleaned after the substrate is completely treated.

6. The substrate treating apparatus of claim 2, wherein the inert gas supply module sprays the inert gas at high pressure.

7. The substrate treating apparatus of claim 6, wherein the inert gas supply module sprays the inert gas at a pressure higher than a pressure for supplying a refrigerant to a cooling member installed in the electrostatic chuck.

8. The substrate treating apparatus of claim 2, wherein the inert gas supply module controls a pressure for spraying the inert gas independently of a pressure for supplying a refrigerant to a cooling member installed in the electrostatic chuck.

9. The substrate treating apparatus of claim 2, wherein the electrostatic chuck includes a base plate and the dielectric layer adsorbing and supporting the substrate seated on an upper portion while being disposed on the base plate,
the inert gas supply module includes:
an inert gas supply source storing and providing the inert gas; and
an inert gas moving line formed by passing through the base plate and the dielectric layer and connected to the inert gas supply source to provide a moving path of the inert gas.

10. The substrate treating apparatus of claim 9, wherein the inert gas moving line is provided as a plural number, and each of the inert gas moving lines independently provides the moving path of the inert gas.

11. The substrate treating apparatus of claim 10, wherein the plurality of inert gas moving lines are disposed to be spaced apart from each other at a predetermined interval in the area between the dielectric layer and the focus ring.

12. The substrate treating apparatus of claim 2, wherein the drain module removes the by-product downward from the area between the dielectric layer and the focus ring.

13. The substrate treating apparatus of claim 2, wherein the drain module removes the by-product while the substrate is treated.

14. The substrate treating apparatus of claim 2, wherein the drain module removes the by-product while the dielectric layer and the focus ring are cleaned after the substrate is completely treated.

15. The substrate treating apparatus of claim 9, wherein the drain module includes:
a by-product moving line formed by passing through the base plate and the dielectric layer, providing a moving path of the by-product; and
a drain pump connected to the by-product moving line.

16. The substrate treating apparatus of claim 15, wherein the by-product moving line is provided as a plural number, and each of the by-product moving lines independently provides the moving path for the by-product.

17. The substrate treating apparatus of claim 16, wherein the plurality of by-product moving lines are disposed to be spaced apart from each other at a predetermined interval in the area between the dielectric layer and the focus ring, and are respectively disposed in an area where the plurality of inert gas moving lines are spaced apart from each other.

18. The substrate treating apparatus of claim 15, wherein the drain pump sucks and discharges the by-product at high pressure through the by-product moving line.

19. A substrate treating apparatus comprising:
a chamber housing providing a space in which a substrate is treated;
a substrate support unit disposed inside the chamber housing, supporting the substrate by including a base plate, a dielectric layer adsorbing and supporting the substrate seated on an upper portion in a state that it is disposed on the base plate, and a focus ring surrounding an outer edge area of the dielectric layer;
a showerhead unit disposed inside the chamber housing, providing a process gas;
a plasma generating unit generating plasma for treating the substrate inside the chamber housing by using the process gas; and
a by-product removal unit preventing a by-product generated in the process of treating the substrate from being adsorbed to or remaining in an area between the dielectric layer and the focus ring,
wherein the by-product removal unit includes an inert gas supply module for spraying an inert gas into the area between the dielectric layer and the focus ring, and a drain module for removing the by-product from the area between the dielectric layer and the focus ring,
the inert gas supply module sprays the inert gas upward in the area between the dielectric layer and the focus ring,
provides the inert gas while the substrate is treated or the dielectric layer and the focus ring are cleaned after the treatment of the substrate is completed,
sprays the inert gas at high pressure which is higher than a pressure for supplying a refrigerant to a cooling member installed in the electrostatic chuck,
controls the pressure for spraying the inert gas independently of control of the pressure for supplying the refrigerant to the cooling member installed in the electrostatic chuck, and
includes an inert gas supply source storing and providing the inert gas, and an inert gas moving line formed by passing through the base plate and the dielectric layer and connected to the inert gas supply source to provide a moving path of the inert gas,
the inert gas moving line is provided as a plural number, and each of the plurality of inert gas moving lines independently provides the moving path of the inert gas, and the plurality of inert gas moving lines are disposed to be spaced apart from each other at a predetermined interval in the area between the dielectric layer and the focus ring,
the drain module removes the by-product downward from the area between the dielectric layer and the focus ring, and removes the by-product while the substrate is treated or the dielectric layer and the focus ring are cleaned after the treatment of the substrate is completed, and
includes a by-product moving line formed by passing through the base plate and the dielectric layer, providing a moving path of the by-product, and a drain pump connected to the by-product moving line, and
the by-product moving line is provided as a plural number, and each of the plurality of by-product moving lines independently provides the moving path of the by-product, and the plurality of by-product moving lines are disposed to be spaced apart from each other at a predetermined interval in the area between the dielectric layer and the focus ring, and the plurality of inert gas moving lines are respectively disposed in the area where the plurality of inert gas moving lines are spaced apparat from each other.

20. A substrate treating method comprising:
treating a substrate by using a substrate treating apparatus;
cleaning the inside of the substrate treating apparatus when the substrate is completely treated; and
removing a by-product generated in the process of treating the substrate while spraying an inert gas into an area between a focus ring and a dielectric layer included in a substrate support unit of the substrate treating apparatus,
wherein the spraying of the inert gas and the removal of the by-product are performed while the substrate is treated or the inside of the substrate treating apparatus is cleaned.
